(19) United States
(12) Patent Application Publication
(10) Pub. No.: US 2005/0207120 A1
(43) Pub. Date: Sep. 22, 2005

(54) Thermal module with heat reservoir and method of applying the same on electronic products

(75) Inventors: Ming-Hsi Tseng, Sanhsia Town (TW); Heng-Chieh Chien, Taipei (TW); Chih-Yao Wang, Hsinchu (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 10/978,451

(22) Filed: Nov. 2, 2004

(30) Foreign Application Priority Data
Mar. 16, 2004 (TW) 93106912

(51) Int. Cl. H05K 7/20

(52) U.S. Cl. 361/700; 361/695; 361/704

(57) ABSTRACT

The present invention discloses a thermal module with heat reservoir, which is arranged with respect to a chip, and the thermal module comprises: a housing, disposed at a appropriate position corresponding to the chip and made of a material of high heat conductivity; a phase change material, disposed within the housing, capable of changing from a first state to a second state by absorbing heat and changing from the second state to the first state by releasing the heat stored therein; wherein the thermal module can be either mounted on the chip at an appropriate location or disposed at a location separated from the chip by an appropriate distance, in addition, the phase change process of the phase change material changing between the first state and the second state can be either a physical process or a chemical process.

### FIELD OF THE INVENTION

The present invention relates to a thermal module with heat reservoir and method of applying the same on electronic products, and more particularly, to a thermal module with heat reservoir capable of transforming heat generated by an integrated circuit (IC) into latent heat stored in the heat reservoir for enabling the IC to keep a constant working temperature, such that the electronic products using the thermal module not only have a better heat dissipating capability, but also have a better operating stability since it is able to avoid the damage or break down caused by an abrupt temperature raising of power burst.

### BACKGROUND OF THE INVENTION:

With rapid advance of communication technology, there are increasing demands for high performance integrated circuit such as microprocessors. However, the better performance the IC is, the more heat it will generate, and the heat generated by the IC must be removed to insure that the working temperature thereof do not exceed a specified level. In this regard, the thermal module for removing heat from the IC has become an essential part of the IT industry.

As the advance of ICs, the thermal module also evolves to have better heat dissipating capability and operating stability so as to conform with the increasing heat generated by current electronic products, from the early thermal module with a simple combination of fan and fin to a recent combination of fan, fin and heat pipe. However, facing the ICs of next generation, current thermal modules available on the market can not meet the challenge. It is desirable to have a new thermal module capable of effectively and reliably carrying away increasing amount of heat generated by the next generation ICs.

Please refer to FIG. 1, which is a schematic representation showing a conventional thermal module of desktop personal computer. The thermal module of FIG. 1 is a design primarily consisted of a fan 10, a heat sink 11 and a heat spreader 12, and is mounted on a chip 13. The thermal module 10 is primary being used in the electronic products with large casing and has about 70 W heat dissipating capability depending on the dimension of the fan 10 therein and the size of the thermal module 10.

Please refer to FIG. 2, which is a schematic representation showing a conventional thermal module of notebook computer. The thermal module of FIG. 2 is a design consisted of a fan 20, a heat sink 21, a heat pipe 22 and a heat spreader 23, in response to the limit of narrow space for storing the same provided in the notebook computer. Using the thermal module, the heat generated by the chip 24 is transferred to the fins 21 through the heat pipe 22 and then is removed by the airflow of the fan 20. The heat dissipating capability of the thermal module of FIG. 2 is about 30 W ˜40 W.

In view of the above description, the conventional thermal module has at least the shortcomings as following:
1. The maximum heat dissipating capability is limited that it is insufficient for high-speed IC chips.
2. The selection and combination of the thermal module design is limited such that the design of the electronic products applying the same is also limited.
3. The power consumed by the conventional thermal module is relatively huge.
4. The instability of the conventional thermal module during heat dissipating will severely shorten the durability and reliability of the IC chip.
5. The design flexibility of the conventional thermal module is limited since it cannot integrate and cooperate in other applications.

### SUMMARY OF THE INVENTION

The primary object of the invention is to provide a thermal module with heat reservoir and method of applying the same on electronic products, which is capable of providing sufficient heat dissipating capability for high-speed IC chips.

The second object of the invention is to provide a thermal module with heat reservoir and method of applying the same on electronic products, which is capable of reducing the power consumed by the same and thus reducing the overall power consumption of the electronic product.

It is another object of the invention to provide a thermal module with heat reservoir and method of applying the same on electronic products, which is capable of ensuring the stability of the same during heat dissipating and thus ensuring the durability and reliability of the IC chip.

Yet, another object of the invention is to provide a thermal module with heat reservoir and method of applying the same on electronic products, which is capable of integrating and cooperating with other heat dissipating devices so as to increase the design flexibility of the same.

To achieve the abovementioned objectives, the present invention provides a thermal module with heat reservoir, arranged with respect to a chip, the thermal module comprising: a housing, disposed at a appropriate position corresponding to the chip and made of a material of high heat conductivity; a phase change material, disposed within the housing, capable of changing from a first state to a second state by absorbing heat and changing from the second state to the first state by releasing the heat stored therein; wherein the thermal module can be either mounted on the chip at an appropriate location or disposed at a location separated from the chip by an appropriate distance.

The method of applying the thermal module with heat reservoir on electronic products of the present invention, comprises the steps of:
(a) providing a chip and a thermal module with heat reservoir, wherein the thermal module with heat reservoir is disposed with respect to the chip;
(b) generating heat by the chip while the chip is being turned on;
(c) transferring heat generated by the chip to be absorbed by the thermal module with heat reservoir, such that a phase change material therein changes from a first state to a second state;
(d) turning off the chip;
(e) (e) releasing the heat absorbed and stored in the thermal module with heat reservoir, such the phase change material therein changes from the second state to the first state.

### BRIEF DESCRIPTION OF THE DRAWINGS

FIG. 1 is a schematic representation showing a conventional thermal module of desktop personal computer.

FIG. 2 is a schematic representation showing a conventional thermal module of notebook computer.

FIG. 3 is an exploded diagram showing a heat absorber according to a preferred embodiment of the present invention.

FIG. 4A˜FIG. 4C are structural diagrams showing the enforcements of the heat absorber according to the present invention.

FIG. 5 is a schematic representation showing the first preferred embodiment of the present invention.

FIG. 6 is a schematic representation showing the second preferred embodiment of the present invention.

FIG. 7 is a schematic representation showing the third preferred embodiment of the present invention.

FIG. 8 is a schematic representation showing the fourth preferred embodiment of the present invention.

FIG. 9 is a schematic representation showing the fifth preferred embodiment of the present invention.

FIG. 10 is a schematic representation showing the sixth preferred embodiment of the present invention.

FIG. 11 is a flow chart illustrating the method of applying the thermal module with heat reservoir on electronic products of the present invention

FIG. 12 is a schematic diagram showing the temperature variation during a heat dissipating process according to a preferred embodiment of the present invention.

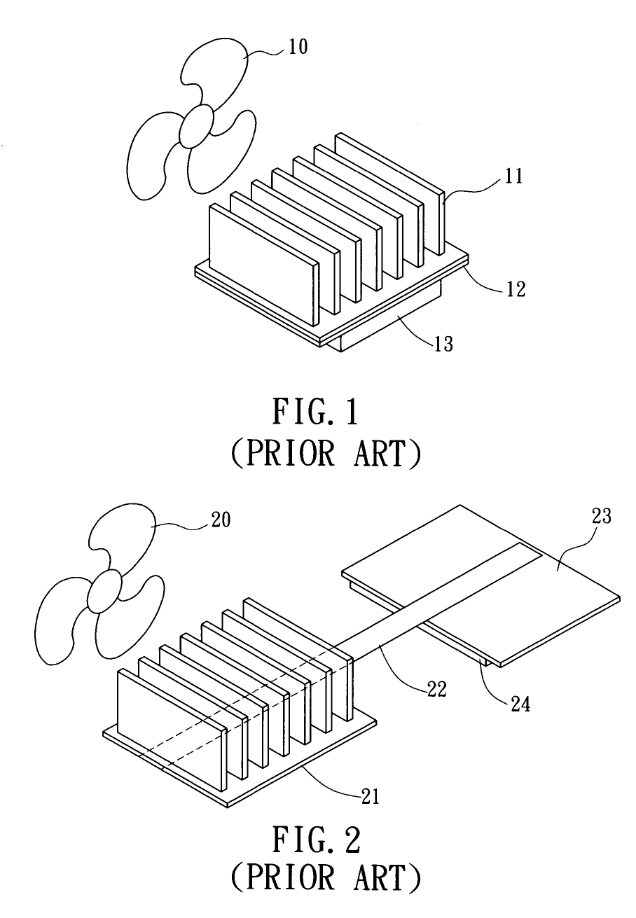

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

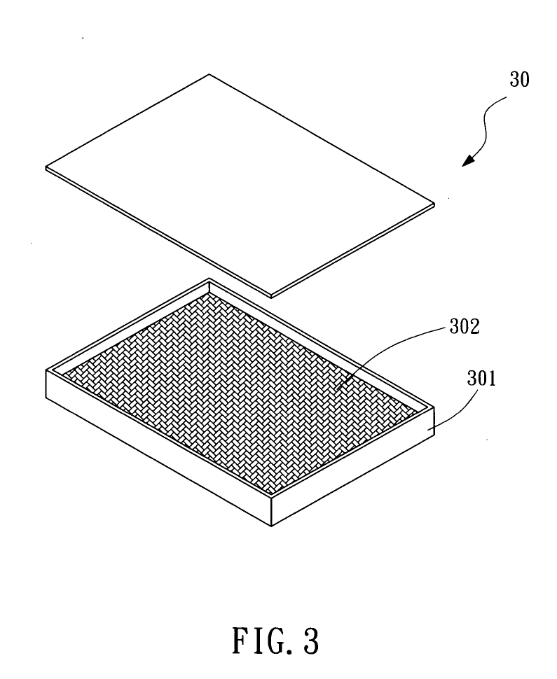

Please refer to FIG. 3, which is an exploded diagram showing a heat absorber 30 according to a preferred embodiment of the present invention. The heat absorber 30 of the invention uses an isothermal process of a material stored therein to absorb heat. The heat absorber 30 is an airtight structure consisted of a housing 301 and a phase change material. The housing 301 is made of a material of high heat conductivity that is not reacting with the phase change material 302. The phase change material 302 is disposed within the housing 301, and is capable of changing from a first state to a second state by absorbing heat and changing from the second state to the first state by releasing the heat stored therein.

The phase change of the phase change material 302 from the first state to the second state and from the second state to the first state can either be a physical process or a chemical process, for instance, it can be a physical phase change process between water and ice, or it can be a chemical phase change process of a dehydration reaction of crystalline formation. The phase change material can be a material selected from the group consisting of water, calcium chloride, Magnesium Sulfate, etc. Take the dehydration reaction of calcium chloride for instance, whose chemical reaction formula and latent heat of the same is as following while temperature is between 20° C. and 40° C.:
CaCl₂.6H₂O(solid state)→CaCl₂+6H₂O(liquid state) ΔQ=1920 J/g

When 200 g calcium chloride is used as the phase change material of the heat absorber 30, the total heat capacity will be 200*1920=384000 J. When the heat source is about 40 W, the insulated heat absorber 30 can store heat lasting for a period of time calculated as following:
384000/40=9600 sec=2.67 hour.

However, since the housing 301 is made of a material with preferred heat conductivity, it will dissipate heat naturally by convention during the heat storage process that the foregoing heat storage period can be extended to at least 3 hours. If a conventional thermal module is integrated with the heat absorber 30 to form a thermal module with heat reservoir, the heat dissipating capability of the newly formed thermal module will be at least 40 W/3 hrs. In this regard, the current thermal module used in notebook computer is about 30 W ˜40 W and thus the heat absorber 30 is fully capable of replacing the function of the thermal module during normal operation, such that the fan therein can be turned off for enabling the notebook computer to consume less power and generate less noise.

When 20 g calcium chloride is used as the phase change material of the heat absorber 30, the total heat capacity will be 20*1920=38400 J. When the heat source is about 5 W, the insulated heat absorber 30 can store heat lasting for a period of time calculated as following:
384000/40=9600 sec=2.13 hour.
The 5 W heat source is equivalent to a heat source of those small hand-held electronic devices such as cellular phone and PDA. Since those kind of small hand-held electronic devices usually is not going to be operated continuously for a period of time longer than 2.13 hours, in addition that the heat absorbed is not insulated, 20 g of additional weight from the heat absorber 30 is a cost-effective solution for solving the heat dissipating problem. Moreover, a better heat dissipating capability can be provided by increasing the amount of phase change material in the heat absorber 30, or by using a detachable heat absorber 30 with different amount of phase change material therein.

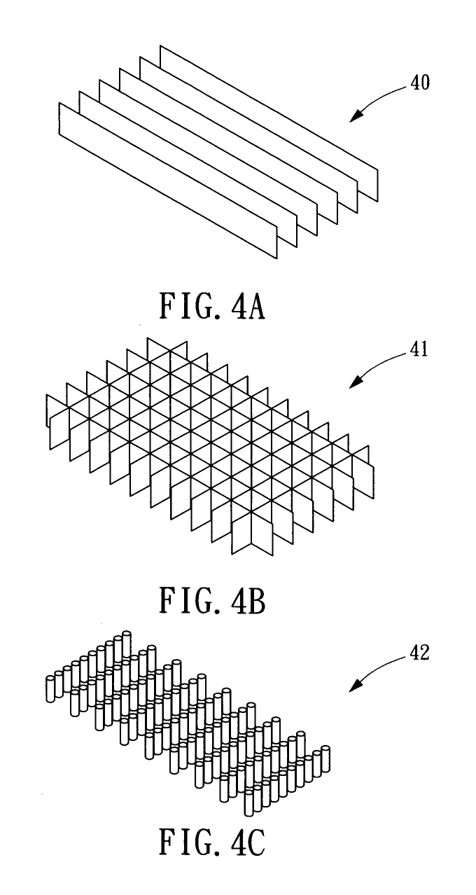

Please refer to FIGS. 4A, 4B and 4C, which are structural diagrams showing the enforcements of the heat absorber according to the present invention. In order to improve the uniformity of heat distribution and enhance the structure integrity, several different formations can be arranged inside the heat absorber as required, such as a bar formation 40, a grid formation 41, and a column formation 42, etc.

Please refer to FIG. 5, which is a schematic representation showing the first preferred embodiment of the present invention. The heat absorber 50 is mounted on the chip 51, i.e. the heat absorber 50 is disposed directly on the heat source, that is the kind of design suitable for those small electronic products of low heat, high heat concentration or short operating time such as cellular phone, PDA, etc. The design as seen in FIG. 5 will not consume additional power or create noise for dissipating heat. The heat absorber 50 and the chip 51 can be glued together or connected by buckling, in addition, a layer of thermal pad can be added in between the heat absorber 50 and the chip 51 for increasing the uniformity of thermal conducting.

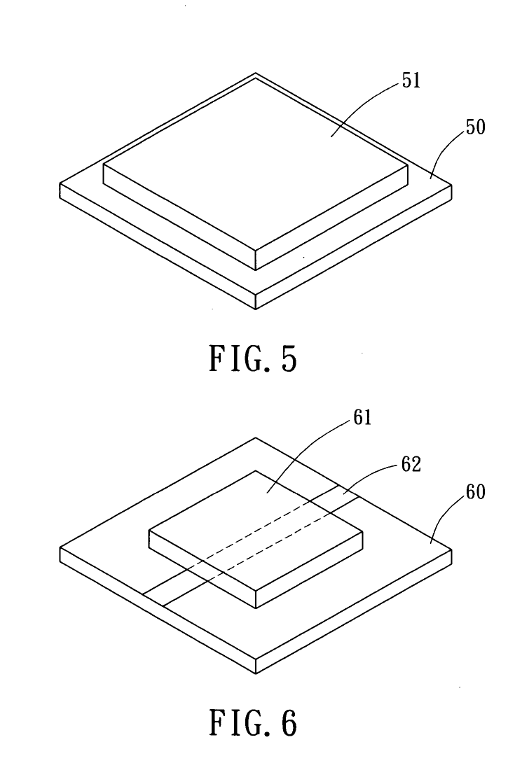

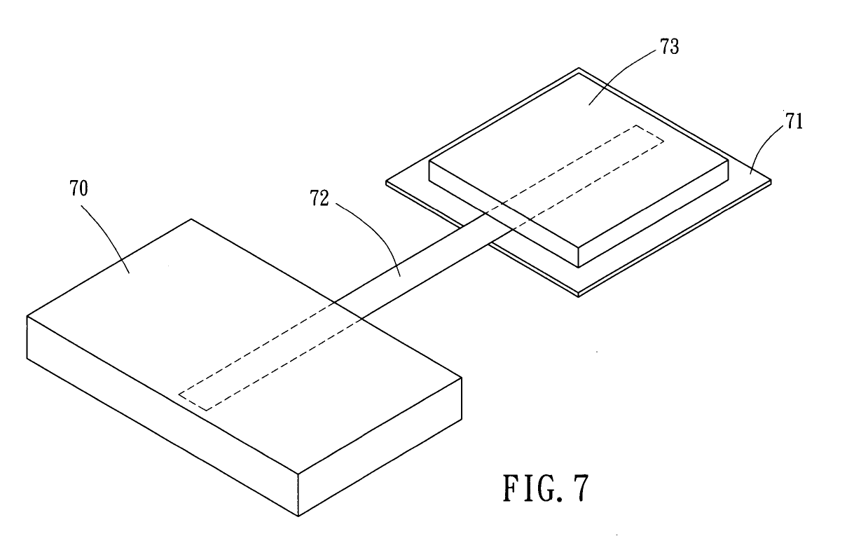

Please refer to FIG. 6, which is a schematic representation showing the second preferred embodiment of the present invention. As seen in FIG. 6, the heat pipe 62 is weld onto the surface of the heat absorber 60, or disposed inside the heat absorber 60 that it can enhance the uniformity of temperature distribution of the heat absorber 60. In addition, it can increase the heat dissipating efficiency of the heat absorber 60 especially when the heat absorber 60 has a relative larger surface area or when the housing of the heat absorber 60 is made of a material with lesser thermal conductivity. In this regard, the thermal module of FIG. 6 is suitable to solve the heat dissipating problem of electronic products with heat source of high heat concentration. Similar to that of FIG. 5, the thermal module consisted of heat pipe 62 and heat absorber 60 is mounted on the chip 61.

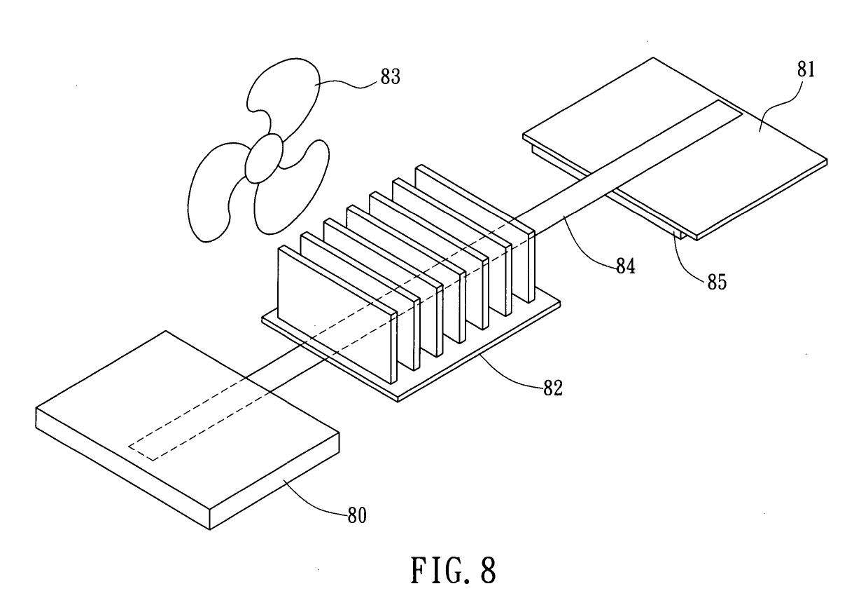

Please refer to FIG. 7, which is a schematic representation showing the third preferred embodiment of the present invention. In order to accommodate all required parts in the limited space provided by the current smaller, lighter electronic product, it is common that the space on top or below the chip is not big enough for any kind of heat-dissipating thermal module. Therefore, it is required to be able to transfer heat generated by the chip to another location suitable for the heat-dissipating thermal module. In this preferred embodiment, a thermal module with heat reservoir is provided capable of accomplishing the foregoing heat transfer, comprising: a heat absorber 70, an isothermal plate 1 and a heat pipe 72, wherein the heat pipe 72 can be flatten or bended, or can be a plate in response to the requirement of different designs. An end of the heat pipe 72 is weld onto the heat spreader 71 while the other end of the heat pipe 72 is either weld at the surface of the heat absorber 70, or being inserted into the interior of the heat absorber 70. The heat spreader is being disposed on the chip 73 for improving the uniformity of heat conducting, and is made of metal with preferred thermal conductivity such as copper and aluminum. This preferred embodiment is suitable for those electronic products of less heat generated and larger surface area.

Please refer to FIG. 8, which is a schematic representation showing the fourth preferred embodiment of the present invention. The thermal module with heat reservoir of FIG. 8 comprises: a heat absorber 80, a heat spreader 81, a heat sink 82, a fan 83 and a heat pipe 84, wherein the heat absorber 80 is serially connected to the plural fins 83 such that excess heat generated by the chip 85 is transferred and absorbed by the heat absorber 80 only when the heat dissipating capability provided by the combination of heat sink 82 and fan 83 is insufficient. The thermal module 80 is adapted for electronic products suffering “power burst”. Similarly, the heat pipe 84 can be flatten or bended in response to the requirement of different designs, and an end of the heat pipe 84 is weld onto the heat spreader 81 or heat sink 82 while the other end of the heat pipe 84 is either weld at the surface of the heat absorber 80, or being inserted into the interior of the heat absorber 80.

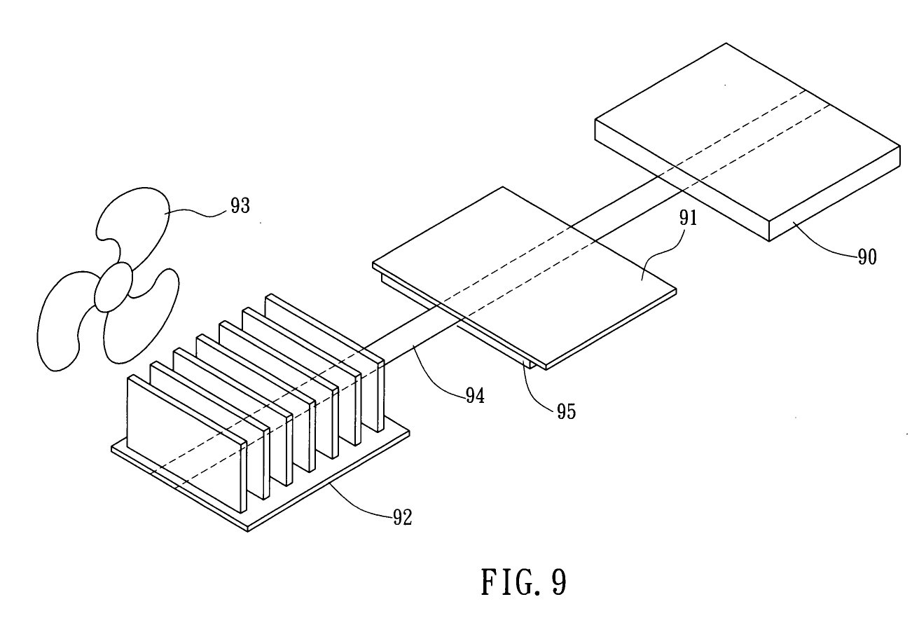

Please refer to FIG. 9, which is a schematic representation showing the fifth preferred embodiment of the present invention. The thermal module with heat reservoir of FIG. 9 comprises: a heat absorber 90, a heat spreader 91, a heat sink 92, a fan 93 and a heat pipe 94, wherein the heat absorber 80 and the heat sink 83 are parallel-connected such that the thermal module can be operate with less power consumption and smaller noise by controlling the speed of the fan 93 as well as solve the heat dissipating problem while the chip is operating in high speed. Similarly, the heat pipe 94 can be flatten or bended in response to the requirement of different designs, and an end of the heat pipe 94 is weld onto the heat spreader 91 or heat sink 92 while the other end of the heat pipe 84 is either weld at the surface of the heat absorber 90, or being inserted into the interior of the heat absorber 90. The heat generated by the chip 95 is first transferred to the heat spreader 91, and then a portion of heat is transferred to the heat absorber 90 through the heat pipe 94 while the other portion of heat is transferred to the fins 92 through the heat pipe 94 to be removed by the airflow generated by the fan 93.

The fourth and fifth preferred embodiments of the present invention are more suitable for those electronic products requiring high heat dissipating capability, such as desktop PCs and notebook PCs, etc. Since the heat generated by those product is relatively large, it is preferred to have a heat absorber working simultaneously with the fan and fins.

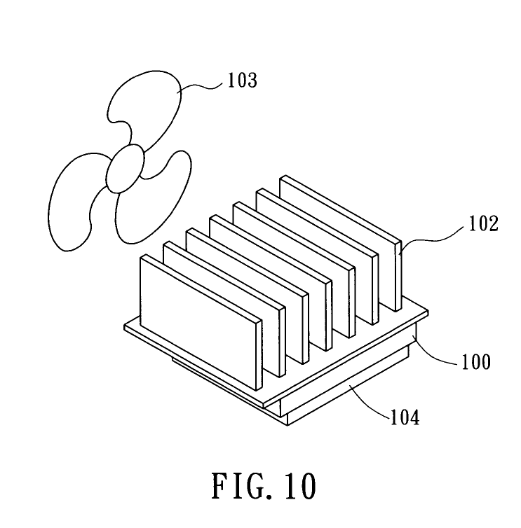

Please refer to FIG. 10, which is a schematic representation showing the sixth preferred embodiment of the present invention. The thermal module of FIG. 10 is suitable for electronic products having enough accommodating space either on top or below the chip thereof, such as desktop PC. The thermal module with heat reservoir is primarily consisted of a heat absorber 100, a heat sink 101 and a fan 102, which is capable of dealing with “power burst” problem by increasing the heat dissipating capability thereof in a predefined period of time, and can reduce the speed of fan 102 for lowing the noise generated by the same while the heat generated by the chip is small. A side of the heat absorber 100 contacts with the chip 104 while the other side of the heat absorber 100 contacts with the heat sink 102. The fan 103 is disposed either on top or at a side of the fins 102. A medium such as thermal pad can be arranged between the heat absorber 100 and the chip 104 for enhancing the surface contact.

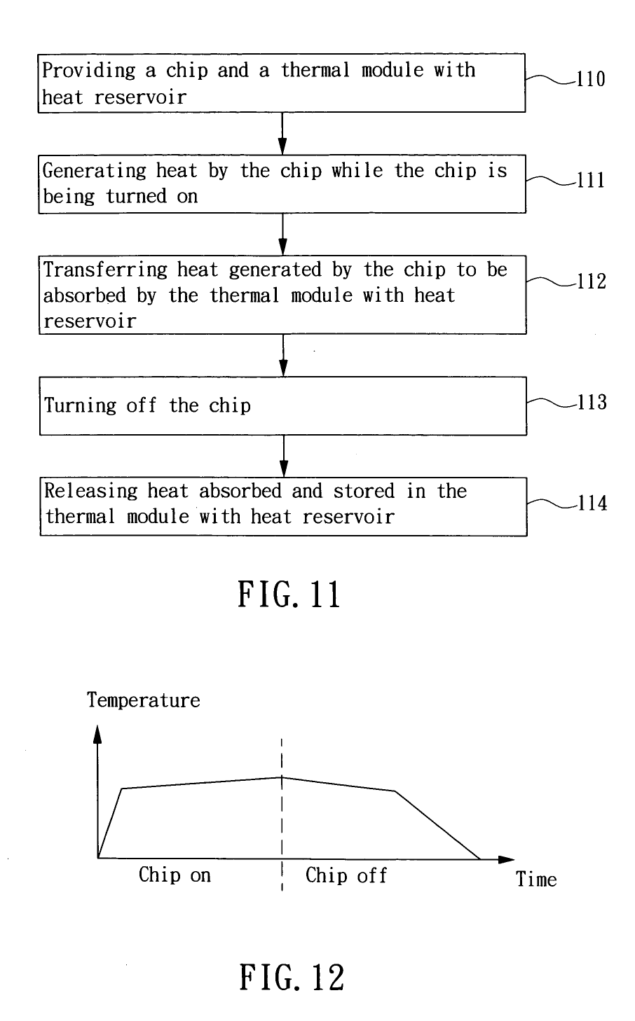

Please refer to FIG. 11, which is a flow chart illustrating the method of applying the thermal module with heat reservoir on electronic products of the present invention. The method comprises the steps of:
Step 110: providing a chip and a thermal module with heat reservoir, wherein the thermal module with heat reservoir is disposed with respect to the chip for absorbing the heat generated by the chip while the chip is being turned on;
Step 111: generating heat by the chip while the chip is being turned on, i.e. turning on a heat source;
Step 112: transferring heat generated by the chip to be absorbed and stored by the thermal module with heat reservoir, such that a phase change material therein changes from a first state to a second state while the phase change can be either a physical process of a chemical process;
Step 113: turning off the chip, i.e. turning off the heat source;
Step 114: releasing the heat absorbed and stored in the thermal module with heat reservoir, such the phase change material therein changes from the second state to the first state following the same physical or chemical process as reverse to the step 112.

Please refer to FIG. 12, which is a schematic diagram showing the temperature variation during a heat dissipating process according to a preferred embodiment of the present invention. The thermal module with heat reservoir will start to absorbing heat while the chip is initiated to generate heat so as to keep the whole assembly within a predefined temperature range for maintaining the chip in a safe operating temperature. When the chip is turned off, the thermal module with heat reservoir will start to release heat store therein and the chip will start to cool down as well. Therefore, the method of applying the thermal module with heat reservoir on electronic products of the present invention not only have heat storage capability, but also can maintain the whole assembly in a constant temperature.

To sum up, the thermal module with heat reservoir and method of applying the same on electronic products, which is capable of providing sufficient heat dissipating capability for high-speed IC chips, and is capable of reducing the power consumed by the same and thus reducing the overall power consumption of the electronic product, and is capable of ensuring the stability of the same during heat dissipating and thus ensuring the durability and reliability of the IC chip, and is capable of integrating and cooperating with other heat dissipating devices so as to increase the design flexibility of the same. With these, the objects and features of the present invention are shown to have great improvement and industrial merits that have not yet disclosed. According to the spirit of the patent law, the present invention undoubtedly meets the requirements.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

1. A thermal module with heat reservoir for electronic products, arranged with respect to a chip, the thermal module comprising:
a housing, disposed at a specific position corresponding to the chip, made of a material of high heat conductivity;
a phase change material, disposed within the housing, capable of changing from a first state to a second state by absorbing heat and changing from the second state to the first state by releasing the heat stored therein; wherein the thermal module can be either mounted on the chip at an appropriate location or disposed at a location separated from the chip by an appropriate distance.

2. The thermal module with heat reservoir as recited of claim 1, wherein the specific position is located in the chip.

3. The thermal module with heat reservoir as recited of claim 1, wherein the housing is connected to a heat sink.

4. The thermal module with heat reservoir as recited of claim 3, wherein the heat sink is connected to a fan.

5. The thermal module with heat reservoir as recited of claim 1, wherein the specific position is a location separated from the chip by a predefined distance.

6. The thermal module with heat reservoir as recited of claim 5, wherein the housing and the chip is connected by a heat pipe.

7. The thermal module with heat reservoir as recited of claim 6, wherein the heat pipe is further connected to a heat sink.

8. The thermal module with heat reservoir as recited of claim 7, wherein the heat sink is connected to a fan.

9. The thermal module with heat reservoir as recited of claim 1, wherein the thermal module with heat reservoir further comprises a column formation.

10. The thermal module with heat reservoir as recited of claim 1, wherein the thermal module with heat reservoir further comprises a grid formation.

11. The thermal module with heat reservoir as recited of claim 1, wherein the thermal module with heat reservoir further comprises a porous formation.

12. The thermal module with heat reservoir as recited of claim 1, wherein the phase change process of the phase change material changing between the first state and the second state is a physical process.

13. The thermal module with heat reservoir as recited of claim 1, wherein the phase change process of the phase change material changing between the first state and the second state is a chemical process.

14. A method of applying the thermal module with heat reservoir on electronic products, comprising the steps of:
(1) providing a chip and a thermal module with heat reservoir, wherein the thermal module with heat reservoir is disposed with respect to the chip;
(2) generating heat by the chip while the chip is being turned on;
(3) transferring heat generated by the chip to be absorbed and stored by the thermal module with heat reservoir, and enabling a phase change material disposed within the thermal module to change from a first state to a second state;
(4) turning off the chip;
(5) releasing the heat stored in the thermal module with heat reservoir, and enabling the phase change material to change from the second state to the first state.

15. The method of claim 14, wherein the phase change process of the phase change material changing between the first state and the second state is a physical process.

16. The method of claim 14, wherein the phase change process of the phase change material changing between the first state and the second state is a chemical process.
